(19) United States
(12) Patent Application Publication
(10) Pub. No.: US 2021/0225741 A1
(43) Pub. Date: Jul. 22, 2021

(54) LEAD FRAME AND ASSEMBLY STRUCTURE

(71) Applicant: Advanced Semiconductor Engineering, Inc., Kaohsiung (TW)

(72) Inventors: I-Jen CHEN, Kaohsiung (TW); Guo-Cheng LIAO, Kaohsiung (TW); Jyun-Chi JHAN, Kaohsiung (TW); Hui-Chen HSU, Kaohsiung (TW)

(73) Assignee: Advanced Semiconductor Engineering, Inc., Kaohsiung (TW)

(21) Appl. No.: 16/749,793

(22) Filed: Jan. 22, 2020

(51) Int. Cl. H01L 23/495; H01L 23/31; H01L 23/00

(52) U.S. Cl. CPC H01L 23/49541; H01L 23/49503; H01L 23/3128; H01L 24/48; H01L 2224/48106; H01L 23/49568; H01L 2224/48247; H01L 2224/48091; H01L 23/4952

(57) ABSTRACT

A lead frame includes a die paddle, a first lead, a second lead, an extending portion and at least one supporting portion. The first lead includes a first main portion and a first I/O portion opposite to the first main portion. The second lead includes a second main portion and a second I/O portion opposite to the second main portion. The first lead and the second lead surround the die paddle. The extending portion extends from the first main portion of the first lead. The supporting portion is connected to the extending portion.

### TECHNICAL FIELD

The present disclosure relates to a lead frame and an assembly structure, and to a lead frame including a plurality of leads surrounding a die paddle, and an assembly structure including the lead frame.

### DESCRIPTION OF THE RELATED ART

As for a semiconductor package such as a quad flat non-leaded package (QFN), a length of each of the leads that surround a die paddle is limited and cannot be further lengthened since the structural strength of the lead becomes weak after manufacturing. Thus, the leads may deform, bend or break during a molding process, and the bonding wires that are bonded on the leads may break or contact with each other to cause a short circuit. However, lengthening the length of the lead may be required when a smaller semiconductor die is attached to the die paddle, to ensure the leads may be still near the smaller semiconductor die and prevent the bonding wire from being longer than its optimum length.

### SUMMARY

In some embodiments, a lead frame includes a die paddle, a first lead, a second lead, an extending portion and at least one supporting portion. The first lead includes a first main portion and a first I/O portion opposite to the first main portion. The second lead includes a second main portion and a second I/O portion opposite to the second main portion. The first lead and the second lead surround the die paddle. The extending portion extends from the first main portion of the first lead. The supporting portion is connected to the extending portion.

In some embodiments, a lead frame includes a die paddle, a plurality of leads, an extending portion and at least one supporting portion. The leads surround the die paddle. The leads include a first lead and a third lead. The first lead includes a first main portion and a first I/O portion opposite to the first main portion. The third lead includes a third main portion and a third I/O portion opposite to the third main portion. The extending portion connects the first main portion of the first lead and the third main portion of the third lead. The supporting portion protrudes from the extending portion.

In some embodiments, an assembly structure includes a substrate and a package structure. The substrate has a top surface and a bottom surface opposite to the top surface. The package structure is disposed adjacent to the top surface of the substrate. The package structure includes a die paddle, a semiconductor die, a first lead, a second lead, an extending portion, at least one supporting portion, a plurality of bonding wires and an encapsulant. The semiconductor die is disposed on the die paddle. The first lead includes a first main portion and a first I/O portion opposite to the first main portion. The second lead includes a second main portion and a second I/O portion opposite to the second main portion. The first lead and the second lead surround the die paddle. The extending portion extends from the first main portion of the first lead. The supporting portion is connected to the extending portion. The bonding wires are used for electrically connecting the semiconductor die to the first lead and the second lead. The encapsulant covers the semiconductor die, the die paddle, the first lead, the second lead, the extending portion, the at least one supporting portion and the bonding wires. A bottom surface of the first I/O portion and a bottom surface of the second I/O portion are bonded to the substrate through a soldering material.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a bottom view of a lead frame according to some embodiments of the present disclosure.

FIG. 2 illustrates a partially enlarged view of FIG. 1.

FIG. 3 illustrates a perspective view of FIG. 2.

FIG. 4 illustrates an enlarged view of a region “B” in FIG. 3.

FIG. 5 illustrates a top perspective view of FIG. 3.

FIG. 6 illustrates a top view of FIG. 5.

FIG. 7 illustrates a cross-sectional view along line 7-7 of FIG. 6.

FIG. 8 illustrates a partially enlarged view of FIG. 7.

FIG. 9 illustrates a cross-sectional view along line 9-9 of FIG. 6.

FIG. 10 illustrates a partially enlarged view of FIG. 9.

FIG. 11 illustrates an enlarged view of a region “A” in FIG. 2.

FIG. 12 illustrates a bottom perspective view of a package structure according to some embodiments of the present disclosure.

FIG. 13 illustrates a cross-sectional view of the package structure of FIG. 12.

FIG. 14 illustrates a cross-sectional view of an assembly structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

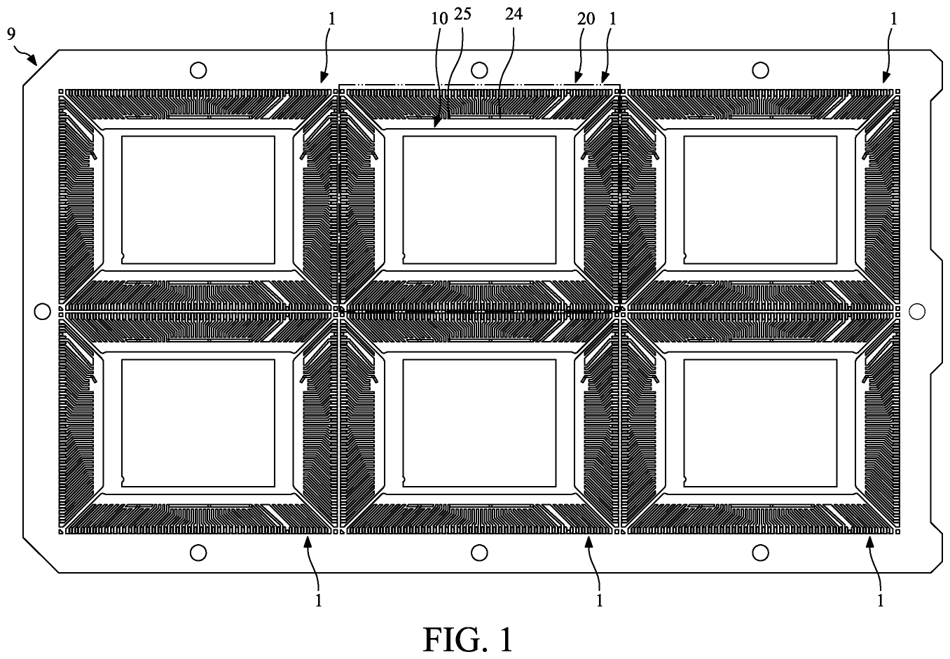

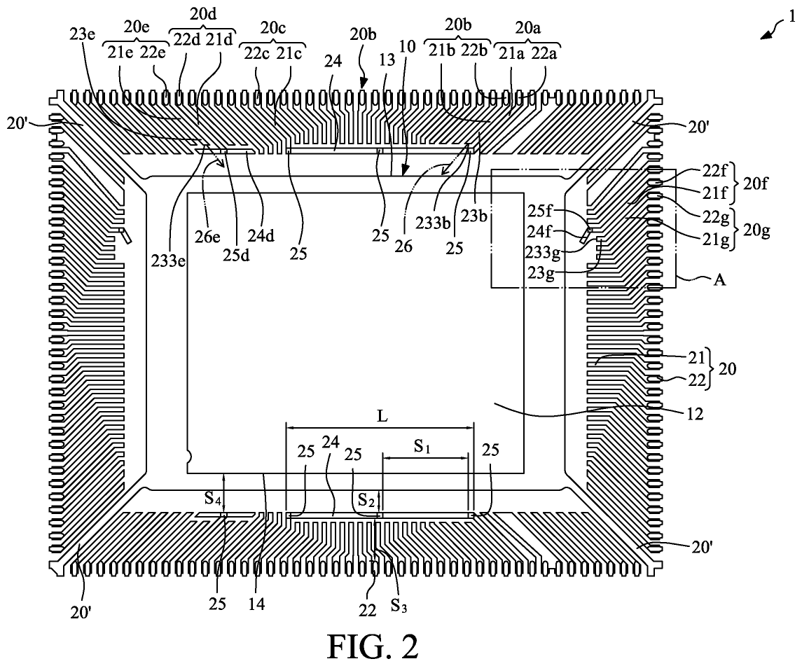

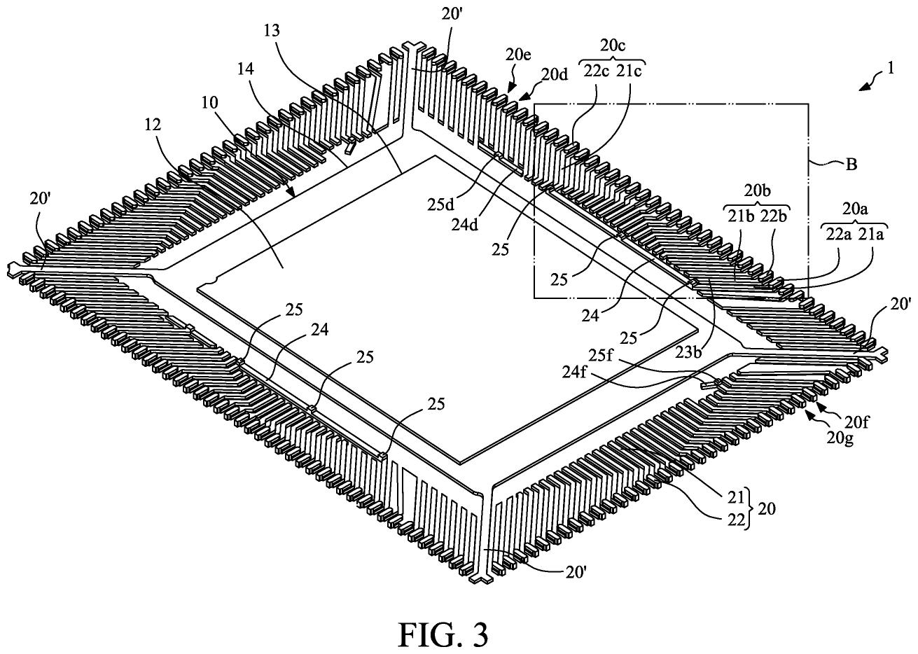

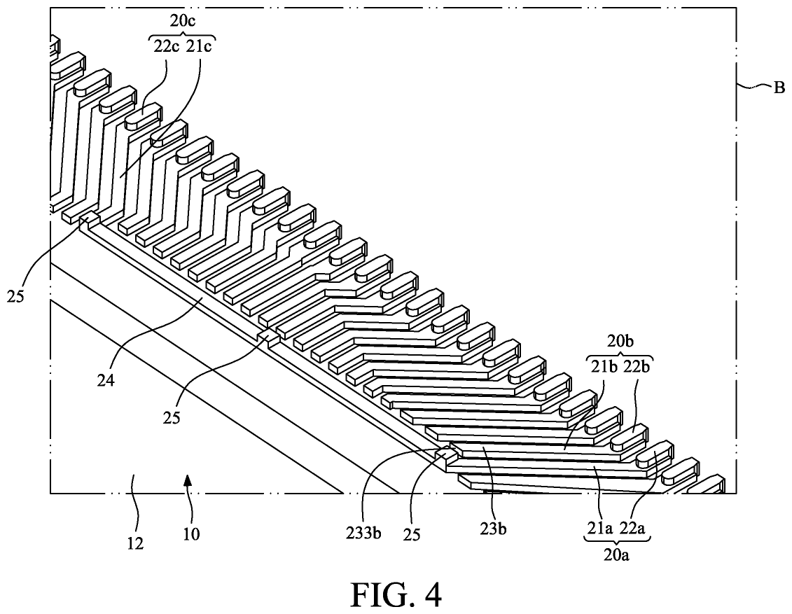

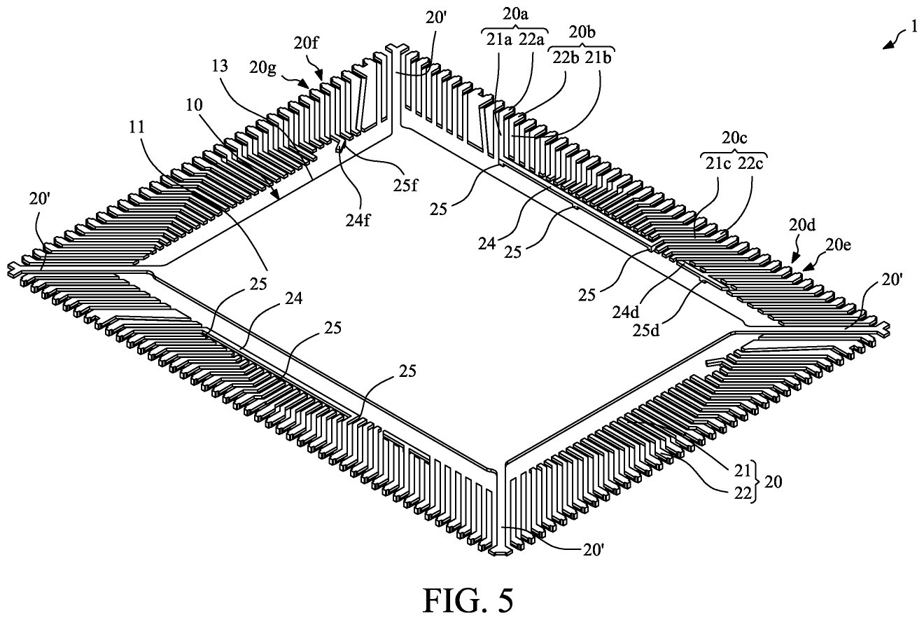

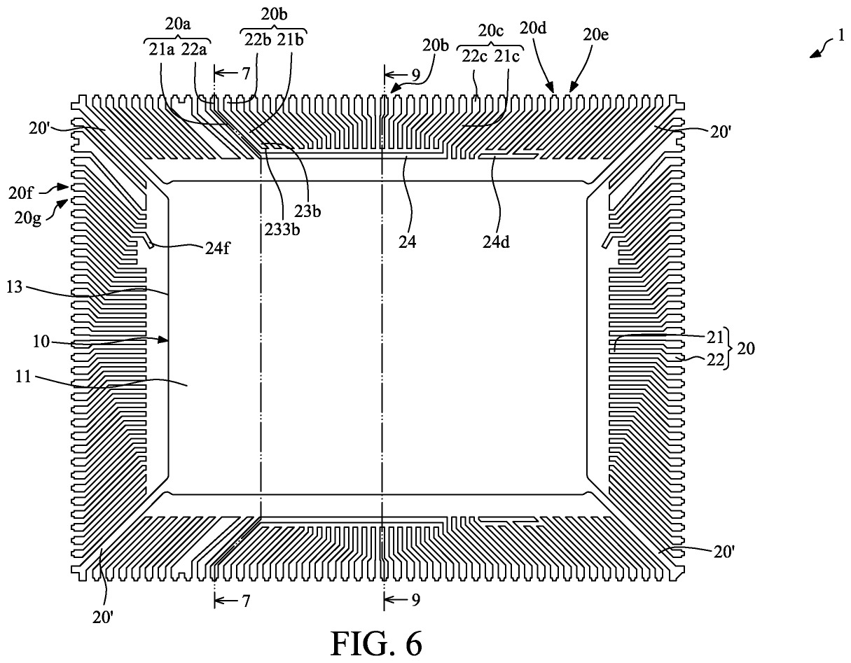

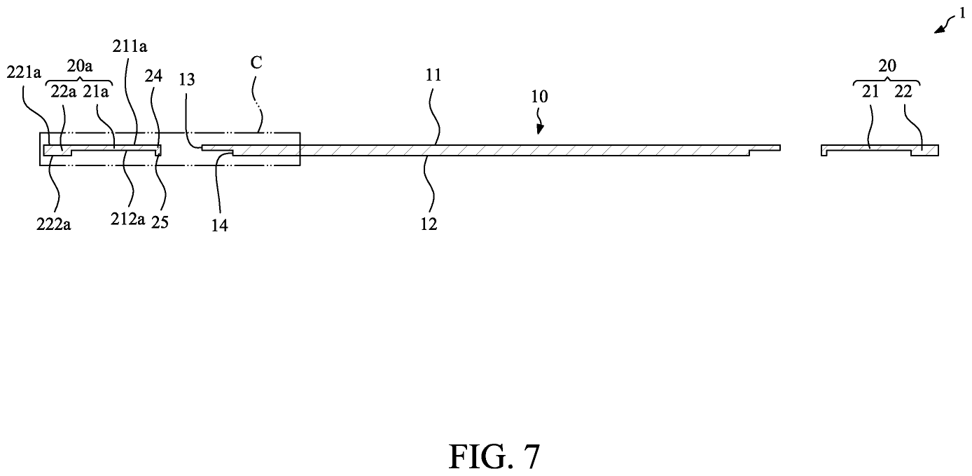

FIG. 1 illustrates a bottom view of a lead frame 9 according to some embodiments of the present disclosure. FIG. 2 illustrates a partially enlarged view of FIG. 1. FIG. 3 illustrates a perspective view of FIG. 2. FIG. 4 illustrates an enlarged view of a region “B” in FIG. 3. FIG. 5 illustrates a top perspective view of FIG. 3. FIG. 6 illustrates a top view of FIG. 5. Referring to FIG. 1, the lead frame 9 may include a plurality of lead frame units 1 arranged in an array. In some embodiments, the lead frame 9 may be a silver plating lead frame or a pre-plated lead frame (PPF). Referring to FIG. 2 to FIG. 6, the lead frame unit 1 includes a die paddle 10, a plurality of leads 20, at least four corner leads 20′, at least one extending portion 24 and a at least one supporting portion 25. In some embodiments, the lead frame unit 1 may be also referred to as a “lead frame”. The die paddle 10 has a top surface 11, a bottom surface 12 (FIG. 7) opposite to the top surface 11 and a side surface extending between the top surface 11 and the bottom surface 12. In some embodiments, the side surface may include an upper side surface 13 corresponding to an upper portion of the die paddle 10 and a lower side surface 14 corresponding to a lower portion of the die paddle 10.

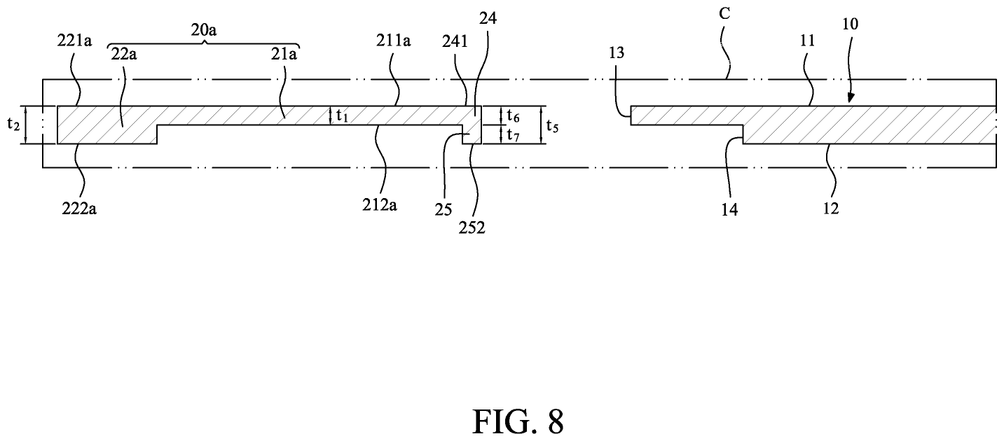

FIG. 7 illustrates a cross-sectional view along line 7-7 of FIG. 6. FIG. 8 illustrates a partially enlarged view of FIG. 7. Referring to FIG. 2 to FIG. 8, the leads 20 surround the die paddle 10. Each of the leads 20 may include a main portion 21 and an input/output (I/O) portion 22 opposite to the main portion 21. In some embodiments, the I/O portion 22 may be exposed from a surface of an encapsulant for externally electrical connection. For example, the leads 20 may include a first lead 20a, a second lead 20b and a third lead 20c. The first lead 20a may include a first main portion 21a and a first I/O portion 22a opposite to the first main portion 21a. The first main portion 21a may have a top surface 211a and a bottom surface 212a opposite to the top surface 211a. The first I/O portion 22a may have a top surface 221a and a bottom surface 222a opposite to the top surface 221a. In some embodiments, the first main portion 21a and the first I/O portion 22a may be formed integrally as a monolithic structure. The top surface 211a of the first main portion 21a and the top surface 221a of the first I/O portion 22a may be at a same surface and at a same level. As shown in FIG. 8, a thickness t₂ of the first I/O portion 22a may be greater than a thickness t₁ of the first main portion 21a. Thus, the bottom surface 212a of the first main portion 21a may be recessed from the bottom surface 222a of the first I/O portion 22a.

In some embodiments, the supporting portion 25 is connected to the extending portion 24. For example, the first lead 20a, the extending portion 24 and the supporting portion 25 may be formed integrally as a monolithic structure. The extending portion 24 may extend from the supporting portion 25 downwardly. Thus, a top surface 211a of the first main portion 21a may be substantially coplanar with a top surface 241 of the extending portion 24 and the top surface 11 of the die paddle 10. A bottom surface 222a of the first I/O portion 22a may be substantially coplanar with a bottom surface 252 of the supporting portion 25 and the bottom surface 12 of the die paddle 10. In addition, a thickness t₂ of the first I/O portion 22a may be substantially equal to a sum thickness t₅ of a thickness t₆ of the extending portion 24 and a thickness t₇ of the supporting portion 25. The thickness t₁ of the first main portion 21a may be substantially equal to the thickness t₆ of the extending portion 24.

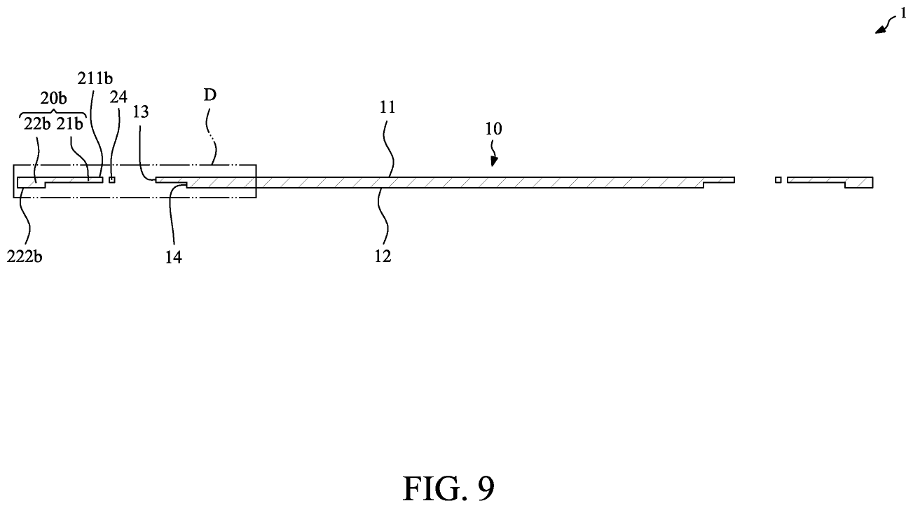

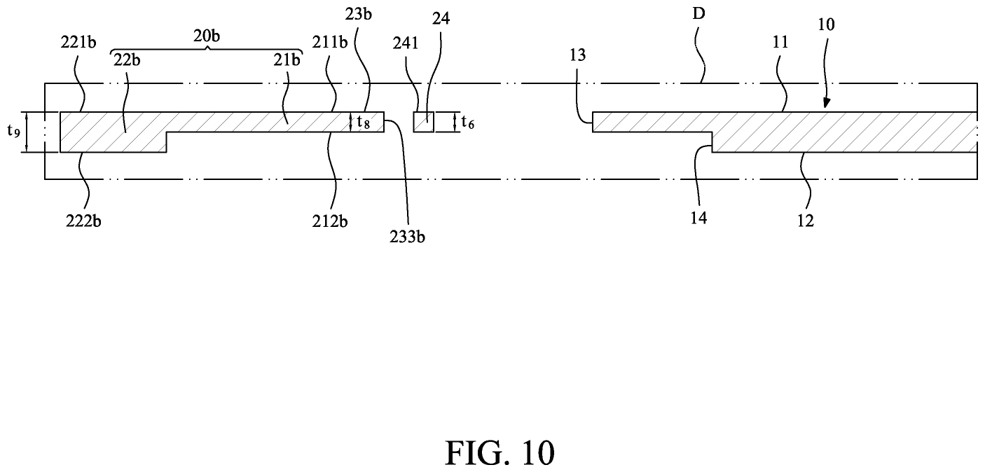

FIG. 9 illustrates a cross-sectional view along line 9-9 of FIG. 6. FIG. 10 illustrates a partially enlarged view of FIG. 9. Referring to FIG. 2 to FIG. 6 and FIG. 9 to FIG. 10, the second lead 20b may include a second main portion 21b and a second I/O portion 22b opposite to the second main portion 21b. The second main portion 21b may have a top surface 211b and a bottom surface 212b opposite to the top surface 211b. The second I/O portion 22b may have a top surface 221b and a bottom surface 222b opposite to the top surface 221b. In some embodiments, the second main portion 21b and the second I/O portion 22b may be formed integrally as a monolithic structure. The top surface 211b of the second main portion 21b and the top surface 221b of the second I/O portion 22b may be at a same surface and at a same level. As shown in FIG. 10, a thickness t₉ of the second I/O portion 22b may be greater than a thickness is of the second main portion 21b. Thus, the bottom surface 212b of the second main portion 21b may be recessed from the bottom surface 222b of the second I/O portion 22b. As shown in FIG. 2 to FIG. 4, the second main portion 21b of the second lead 20b may include a bonding portion 23b (e.g., a bonding end) opposite to the second I/O portion 22b. The bonding portion 23b (e.g., a bonding end) may be used for a bonding wire to be connected to or bonded to. The bonding portion 23b (e.g., a bonding end) may have an end side surface 233b opposite to the second I/O portion 22b and extending between the top surface 211b and the bottom surface 212b of the second main portion 21b. The end side surface 233b of the second lead 20b faces the extending portion 24.

In some embodiments, as shown in FIG. 9 and FIG. 10, a top surface 211b of the second main portion 21b may be substantially coplanar with the top surface 241 of the extending portion 24 and the top surface 11 of the die paddle 10. A bottom surface 222b of the second I/O portion 22b may be substantially coplanar with the bottom surface 12 of the die paddle 10. In addition, the thickness is of the second main portion 21b may be substantially equal to the thickness t₆ of the extending portion 24.

As shown in FIG. 2, an extending direction 26 of the bonding portion 23b (e.g., a bonding end) of the second lead 20b may extend across the extending portion 24. In addition, the first main portion 21a of the first lead 20a is disposed adjacent to and spaced apart from the die paddle 10, and the bonding portion 23b of the second main portion 21b of the second lead 20b is disposed adjacent to and spaced apart from the die paddle 10. The extending portion 24 extends from the first main portion 21a of the first lead 20a, and a portion of the extending portion 24 may be disposed between the die paddle 10 and the bonding portion 23b of the second main portion 21b of the second lead 20b.

As shown in FIG. 2, the extending portion 24 may be substantially parallel with the side surface (e.g., the upper side surface 13) of the die paddle 10. Further, a length L of the extending portion 24 may be greater than or equal to 5 mm. In addition, the at least one supporting portion 25 may include a plurality of supporting portions 25, and a gap S₁ between two adjacent supporting portions 25 may be greater than or equal to 0.2 mm and less than or equal to 10 mm. A gap S₂ between the upper side surface 13 of the die paddle 10 and the supporting portion 25 may be greater than or equal to 0.2 mm and less than or equal to 10 mm. A gap S₄ may be greater than or equal to 0.2 mm and less than or equal to 10 mm. A gap S₃ between the supporting portion 25 and the I/O portion 22 may be greater than or equal to 0.2 mm and less than or equal to 10 mm. As shown in FIG. 3, the supporting portion 25 may be in a pillar shape or bump shape, and a cross section of the supporting portion 25 may be circular, square, elliptical or any desired polygonal shape.

As shown in FIG. 2 and FIG. 3, the leads 20 may further include a third lead 20c. The third lead 20c may include a third main portion 21c and a third I/O portion 22c opposite to the third main portion 21c. The second lead 20b is disposed between the first lead 20a and the third lead 20c. The extending portion 24 connects to the third main portion 21c of the third lead 20c. That is, the extending portion 24 may connect the first main portion 21a of the first lead 20a and the third main portion 21c of the third lead 20c. The extending portion 24 may be a bridge between the first lead 20a and the third lead 20c.

In some embodiments, the first lead 20a, the third lead 20c, the extending portion 24 and the supporting portion(s) 25 are formed integrally as a monolithic structure. An electric potential of the first lead 20a may be equal to an electric potential of the third lead 20c. Further, the second lead 20b may be separated from the extending portion 24. Thus, an electric potential of the second lead 20b may be different from the electric potential of the first lead 20a and the third lead 20c. In addition, a length of the first main portion 21a of the first lead 20a or a length of the third main portion 21c of the third lead 20c may be greater than a length of the second main portion 21b of the second lead 20b. As shown in FIG. 2, there may be a plurality of second leads 20b disposed between the first lead 20a and the third lead 20c.

As shown in FIG. 2 and FIG. 3, the lead frame unit 1 may further include at least one extending portion 24d and at least one supporting portion 25d. The leads 20 may further include a first lead 20d and a second lead 20e. The first lead 20d may include a first main portion 21d and a first I/O portion 22d opposite to the first main portion 21d. In some embodiments, the first main portion 21d and the first I/O portion 22d may be formed integrally as a monolithic structure. Further, the second lead 20e may include a second main portion 21e and a second I/O portion 22e opposite to the second main portion 21e. In some embodiments, the second main portion 21e and the second I/O portion 22e may be formed integrally as a monolithic structure. The second main portion 21e of the second lead 20e may include a bonding portion 23e (e.g., a bonding end) opposite to the second I/O portion 22e. The bonding portion 23e (e.g., a bonding end) may be used for a bonding wire to be connected to or bonded to. The bonding portion 23e (e.g., a bonding end) may have an end side surface 233e opposite to the second I/O portion 22e. The end side surface 233e of the second lead 20e faces the extending portion 24d.

In some embodiments, the supporting portion 25d is connected to the extending portion 24d. For example, the first lead 20d, the extending portion 24d and the supporting portion 25d may be formed integrally as a monolithic structure. The extending portion 24d may extend from the supporting portion 25d downwardly. An extending direction 26e of the bonding portion 23e (e.g., a bonding end) of the second lead 20e may extend across the extending portion 24d. In addition, the first main portion 21d of the first lead 20d is disposed adjacent to and spaced apart from the die paddle 10, and the bonding portion 23e of the second main portion 21e of the second lead 20e is disposed adjacent to and spaced apart from the die paddle 10. The extending portion 24d extends from the first main portion 21d of the first lead 20d, and a portion of the extending portion 24d may be disposed between the die paddle 10 and the bonding portion 23e of the second main portion 21e of the second lead 20e. As shown in FIG. 2, the extending portion 24d may be substantially parallel with the upper side surface 13 of the die paddle 10.

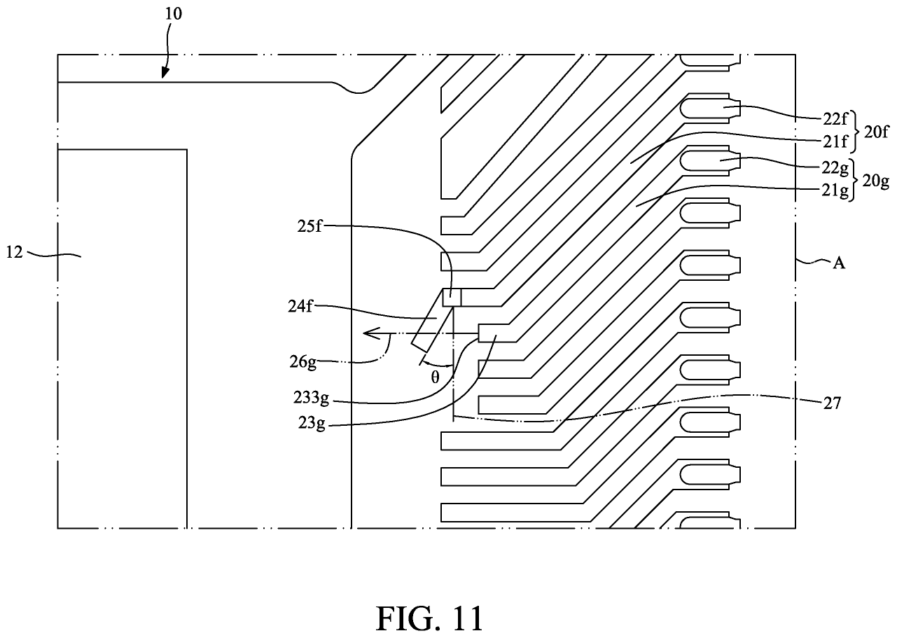

FIG. 11 illustrates an enlarged view of a region “A” in FIG. 2. As shown in FIG. 2, FIG. 3 and FIG. 11, the lead frame unit 1 may further include at least one extending portion 24f and at least one supporting portion 25f. The leads 20 may further include a first lead 20f and a second lead 20g. The first lead 20f may include a first main portion 21f and a first I/O portion 22f opposite to the first main portion 21f. In some embodiments, the first main portion 21f and the first I/O portion 22f may be formed integrally as a monolithic structure. Further, the second lead 20g may include a second main portion 21g and a second I/O portion 22g opposite to the second main portion 21g. In some embodiments, the second main portion 21g and the second I/O portion 22g may be formed integrally as a monolithic structure. The second main portion 21g of the second lead 20g may include a bonding portion 23g (e.g., a bonding end) opposite to the second I/O portion 22g. The bonding portion 23g (e.g., a bonding end) may be used for a bonding wire to be connected to or bonded to. The bonding portion 23g (e.g., a bonding end) may have an end side surface 233g opposite to the second I/O portion 22g. The end side surface 233g of the second lead 20g faces the extending portion 24f.

In some embodiments, the supporting portion 25f is connected to the extending portion 24f For example, the first lead 20f, the extending portion 24f and the supporting portion 25f may be formed integrally as a monolithic structure. The extending portion 24f may extend from the supporting portion 25f downwardly. An extending direction 26g of the bonding portion 23g (e.g., a bonding end) of the second lead 20g may extend across the extending portion 24f In addition, the first main portion 21f of the first lead 20f is disposed adjacent to and spaced apart from the die paddle 10, and the bonding portion 23g of the second main portion 21g of the second lead 20g is disposed adjacent to and spaced apart from the die paddle 10. The extending portion 24f extends from the first main portion 21f of the first lead 20f, and a portion of the extending portion 24f may be disposed between the die paddle 10 and the bonding portion 23g of the second main portion 21g of the second lead 20g. As shown in FIG. 11, an inclination angle θ is between the extending portion 24f and an imaginary plane 27. The imaginary plane 27 may be substantially parallel with the upper side surface 13 of the die paddle 10. The inclination angle θ may be in a range of ±60 degrees.

As shown in FIG. 2 and FIG. 3, the at least four corner leads 20′ correspond to four corners of the die paddle 10 respectively. In some embodiments, the corner leads 20′ may be connected to four corners of the die paddle 10 respectively to support the die paddle 10. The corner leads 20′ may replace four tie bars used in prior art lead frames to increase a number of the leads 20 of the lead frame unit 1 of the lead frame 9. In some embodiments, the corner leads 20′ and the die paddle 10 may be formed integrally as a monolithic structure.

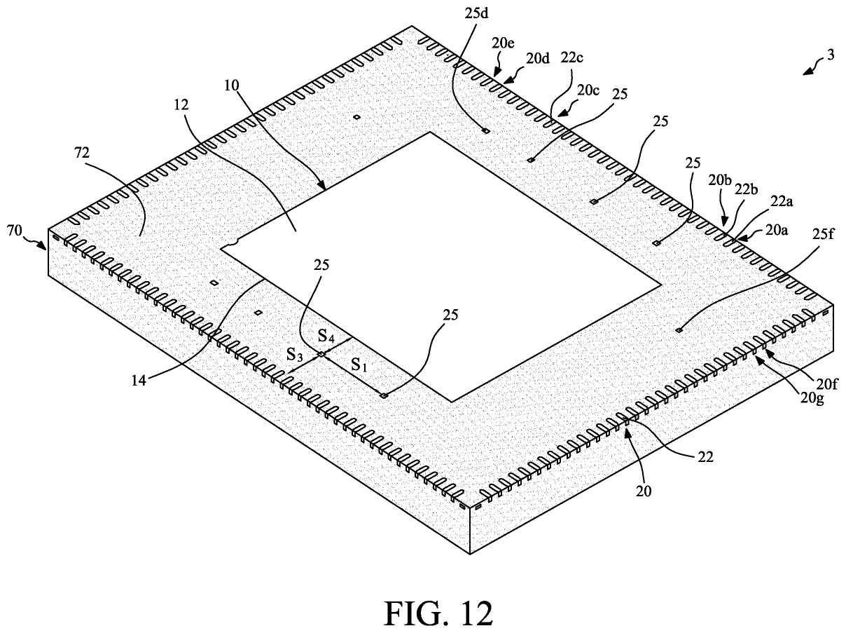

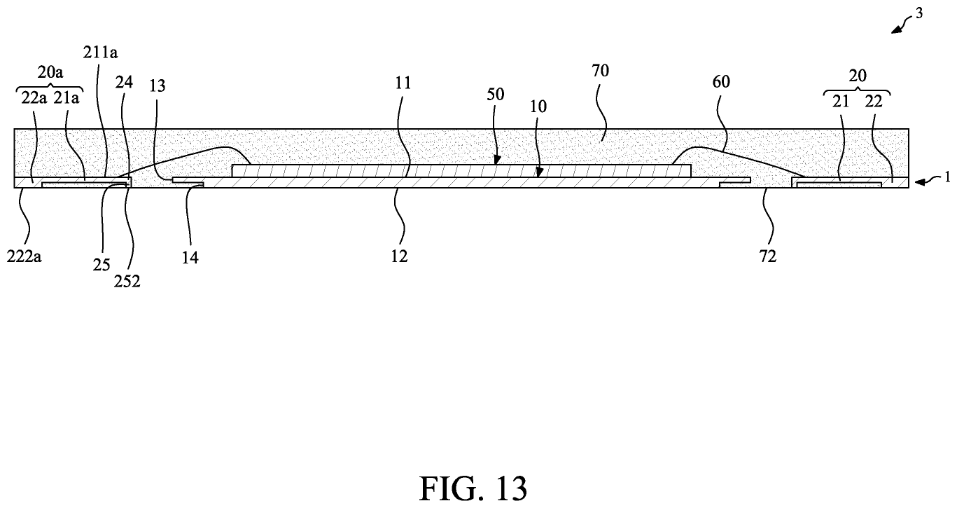

In the embodiment illustrated in FIG. 1 to FIG. 11, the supporting portions 25, 25d, 25f may support the extending portions 24, 24d, 24f during a wire bonding process and a molding process, so as to prevent the extending portions 24, 24d, 24f from deforming, bending or breaking. Thus, the bonding wires that are bonded on the extending portions 24, 24d, 24f may not break or contact with each other to cause a short circuit while the first leads (e.g., the first lead 20a, 20d, 20f), the extending portions (e.g, the extending portions 24, 24d, 24f) and the third lead 20c may deform during the molding process. As a result, the length L of the extending portions 24, 24d, 24f may be lengthened to be greater than about 5 mm, about 8 mm, or about 10 mm. Further, in a package structure 3 (FIG. 12 and FIG. 13), the supporting portions 25, 25d, 25f may be exposed from an encapsulant 70 for heat dissipating. That is, each of the supporting portions 25, 25d, 25f may be a portion of a heat dissipating path. In addition, the exposed supporting portions 25, 25d, 25f may be used as position marks. In some embodiments, the number, arrangement or shape of the supporting portions 25, 25d, 25f on four sides of the lead frame unit 1 may be different from each other, thus, the orientation of the package structure 3 (FIG. 12 and FIG. 13) may be recognized or identified from the exposed supporting portions 25, 25d, 25f In addition, each of the supporting portions 25, 25d, 25f may be an electrostatic discharge (ESD) path.

FIG. 12 illustrates a bottom perspective view of a package structure 3 according to some embodiments of the present disclosure. FIG. 13 illustrates a cross-sectional view of the package structure 3 of FIG. 12. The package structure 3 includes a lead frame unit 1, a semiconductor die 50, a plurality of bonding wires 60 and an encapsulant 70. The lead frame unit 1 of FIG. 12 and FIG. 13 may be the same as the lead frame unit 1 of FIG. 2 through FIG. 11. The semiconductor die 50 disposed on the die paddle 10. For example, a backside surface of the semiconductor die 50 may be adhered to the top surface 11 of the die paddle 10. Further, the bonding wires 60 are used for electrically connecting the semiconductor die 50 to the leads 20 (e.g., the first lead 20a, the second lead 20b and the third lead 20c). For example, the bonding wires 60 may include a first wire bonded to the extending portion 24, and a second wire bonded to the bonding portion 23b of the second main portion 21b of the second lead 20b. In some embodiment, at least two of the bonding wires 60 are bonded to the extending portion 24.

The encapsulant 70 (e.g., a molding compound) covers the semiconductor die 50, the die paddle 10, the leads 20 (e.g., the first lead 20a, the second lead 20b and the third lead 20c), the extending portion(s) 24, 24d, 24f, the at least one supporting portion 25, 25d, 25f and the bonding wires 60. In some embodiments, the bottom surface 72 of the encapsulant 70 may be substantially coplanar with the bottom surface of the I/O portion 22 of the leads 20, the bottom surfaces of the supporting portions 25, 25d, 25f, and the bottom surface 12 of the die paddle 10. For example, the bottom surface 222a of the first I/O portion 22a, the bottom surface 222b of the second I/O portion 22b, the bottom surface of the third I/O portion 22c, the bottom surface 252 of the supporting portion 25 and the bottom surface 12 of the die paddle 10 may be substantially coplanar with the bottom surface 72 of the encapsulant 70, and may be exposed from the bottom surface 72 of the encapsulant 70.

In some embodiments, a bonding layer may be formed or disposed on the exposed bottom surface of the I/O portion 22 of the leads 20, the exposed bottom surfaces of the supporting portions 25, 25d, 25f, and the exposed bottom surface 12 of the die paddle 10. The bonding layer may include at least one metal layer, and a material of the at least one metal layer may be nickel (Ni), palladium (Pd), gold (Au), silver (Ag), and/or pre-solder.

In some embodiments, the supporting portions 25, 25d, 25f are embedded in the encapsulant 70 so as to improve the bonding between the lead frame 9 (or the lead frame unit 1) and the encapsulant 70. That is, the supporting portions 25, 25d, 25f may have the locking function.

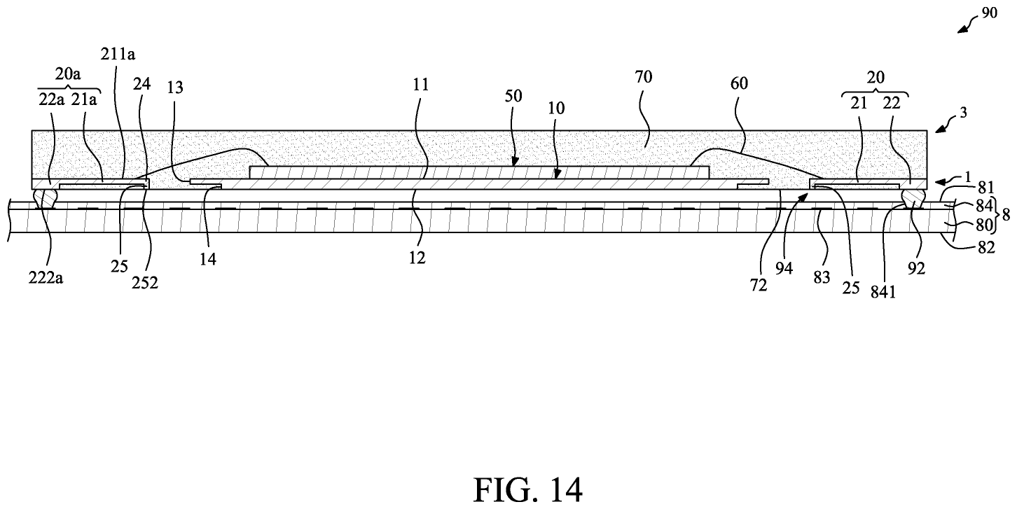

FIG. 14 illustrates a cross-sectional view of an assembly structure 90 according to some embodiments of the present disclosure. The assembly structure 90 may include a substrate 8 and a package structure 3. The substrate 8 has a top surface 81 and a bottom surface 82 opposite to the top surface 81. The substrate 8 may include a main dielectric structure 80, a topmost circuit layer 83 and a topmost protection layer 84. The topmost circuit layer 83 may be disposed on the main dielectric structure 80, and may include at least one trace and at least one pad. The topmost protection layer 84 may be disposed on the topmost circuit layer 83 to cover the topmost circuit layer 83, and may define a plurality of openings 841 to expose portions of the topmost circuit layer 83.

The package structure 3 of FIG. 14 may be the same as the package structure 3 of FIG. 12 and FIG. 13. The package structure 3 may be disposed adjacent to and bonded to the top surface 81 of the substrate 8. As shown in FIG. 14, the bottom surfaces of the I/O portions 22 of the leads 20 may be electrically connected to the topmost circuit layer 83 of the substrate 8 through a soldering material 92. For example, the bottom surface 222a of the first I/O portion 22a, the bottom surface 222b of the second I/O portion 22b and the bottom surface of the third I/O portion 22c are bonded to the topmost circuit layer 83 of the substrate 8 through the soldering material 92. Further, a portion of the soldering material 92 may be disposed in the openings 841. Thus, the positions of the openings 841 may correspond to the I/O portions 22 (e.g., the first I/O portion 22a, the second I/O portion 22b and the third I/O portion 22c) of the leads 20. In some embodiments, there may be no soldering material between the bottom surfaces of the supporting portions 25, 25d, 25f and the top surface 81 of the substrate 8. Thus, a space 94 between a bottom surface of the supporting portion 25, 25d, 25f and the top surface 81 of the substrate 8 may be empty. In addition, the topmost protection layer 84 of the substrate 8 may not define opening under the supporting portions 25, 25d, 25f. Thus, a portion of the topmost protection layer 84 of the substrate 8 under the supporting portions 25, 25d, 25f is free of opening. Each of the supporting portions 25, 25d, 25f may not be a portion of electrical transmission path.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A lead frame, comprising:
a die paddle;
a first lead including a first main portion and a first I/O portion opposite to the first main portion;
a second lead including a second main portion and a second I/O portion opposite to the second main portion, wherein the first lead and the second lead surround the die paddle;
an extending portion extending from the first main portion of the first lead; and
at least one supporting portion connected to the extending portion.

2. The lead frame of claim 1, wherein the second lead has an end side surface opposite to the second I/O portion, and the end side surface of the second lead faces the extending portion.

3. The lead frame of claim 1, wherein the second main portion of the second lead includes a bonding portion opposite to the second I/O portion, and an extending direction of the bonding portion extends across the extending portion.

4. The lead frame of claim 1, wherein the first main portion is disposed adjacent to and spaced apart from the die paddle, the second main portion is disposed adjacent to and spaced apart from the die paddle, and a portion of the extending portion is disposed between the die paddle and the second main portion of the second lead.

5. The lead frame of claim 1, wherein a thickness t₂ of the first I/O portion is greater than a thickness of the first main portion, and a thickness of the second I/O portion is greater than a thickness of the second main portion.

6. The lead frame of claim 1, wherein a thickness of the first I/O portion is substantially equal to a sum thickness of a thickness of the extending portion and a thickness of the supporting portion.

7. The lead frame of claim 1, further comprising a third lead including a third main portion and a third I/O portion opposite to the third main portion, the second lead is disposed between the first lead and the third lead, and the extending portion connects to the third main portion of the third lead.

8. The lead frame of claim 1, wherein the extending portion is substantially parallel with a side surface of the die paddle.

9. The lead frame of claim 1, wherein the at least one supporting portion includes a plurality of supporting portions, and a gap between two adjacent supporting portions is greater than or equal 0.2 mm.

10. The lead frame of claim 1, wherein a gap between a side surface of the die paddle and the at least one supporting portion is greater than or equal 0.2 mm.

11. A lead frame, comprising:
a die paddle;
a plurality of leads surrounding the die paddle, wherein the leads includes:
a first lead including a first main portion and a first I/O portion opposite to the first main portion; and
a third lead including a third main portion and a third I/O portion opposite to the third main portion;
an extending portion connecting the first main portion of the first lead and the third main portion of the third lead; and
at least one supporting portion protruding from the extending portion.

12. The lead frame of claim 11, wherein an electric potential of the first lead is equal to an electric potential of the third lead.

13. The lead frame of claim 11, wherein the leads further includes a second lead disposed between the first lead and the third lead, and separated from the extending portion.

14. The lead frame of claim 13, wherein the second lead includes a second main portion and a second I/O portion opposite to the second main portion, and a length of the first main portion of the first lead is greater than a length of the second main portion of the second lead.

15. An assembly structure, comprising:
a substrate having a top surface and a bottom surface opposite to the top surface; and
a package structure disposed adjacent to the top surface of the substrate, and comprising:
a die paddle;
a semiconductor die disposed on the die paddle;
a first lead including a first main portion and a first I/O portion opposite to the first main portion;
a second lead including a second main portion and a second I/O portion opposite to the second main portion, wherein the first lead and the second lead surround the die paddle;
an extending portion extending from the first main portion of the first lead; and
at least one supporting portion connected to the extending portion;
a plurality of bonding wires electrically connecting the semiconductor die to the first lead and the second lead; and
an encapsulant covering the semiconductor die, the die paddle, the first lead, the second lead, the extending portion, the at least one supporting portion and the bonding wires, wherein a bottom surface of the first I/O portion and a bottom surface of the second I/O portion are bonded to the substrate through a soldering material.

16. The assembly structure of claim 15, wherein the bonding wires includes a first wire bonded to the extending portion, and a second wire bonded to the second main portion of the second lead.

17. The assembly structure of claim 15, wherein at least two of the bonding wires are bonded to the extending portion.

18. The assembly structure of claim 15, wherein a bottom surface of the first I/O portion, a bottom surface of the second I/O portion and a bottom surface of the at least one supporting portion are exposed from a bottom surface of the encapsulant.

19. The assembly structure of claim 15, wherein the extending portion connects to a third lead.

20. The assembly structure of claim 15, wherein a space between a bottom surface of the at least one supporting portion and the top surface of the substrate is empty.
